(19) United States
(12) Patent Application Publication
(10) Pub. No.: US 2007/0039817 A1
(43) Pub. Date: Feb. 22, 2007

(54) Copper-containing pvd targets and methods for their manufacture

(76) Inventors: Brian J Daniels, La Honda, CA (US); Michael E. Thomas, Milpitas, CA (US); Susand D. Strothers, Spokane, WA (US); Wuwen Yi, Veradale, WA (US); Anil S. Bhanap, Milpitas, CA (US); Eal H. Lee, Milpitas, CA (US); Cara L. Hutchinson, Scotts Valley, CA (US); Christie J. Hausman, Spokane, WA (US)

Correspondence Address: WELLS ST. JOHN P.S., 601 WEST FIRST AVE, SUITE 1300, SPOKANE, WA, 99201, US

(21) Appl. No.: 10/549,401

(22) PCT Filed: Aug. 20, 2004
(86) PCT No.: PCT/US04/27090

§ 371 Date: Feb. 8, 2006

Related U.S. Application Data
(60) Provisional application No. 60/497,149, filed on Aug. 21, 2003.

(51) Int. Cl. C23C 14/00; C23C 14/32

(52) U.S. Cl. 204/298.12; 204/192.1

(57) ABSTRACT

The invention includes a physical vapor deposition target containing copper and at least two additional elements selected from Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn and Zr, a total amount of the at least two additional elements being from 100 ppm to 10 atomic %. The invention additionally includes thin films and interconnects which contain the mixture of copper and at least two added elements. The invention also includes forming a copper-containing target. A mixture of copper and two or more elements is formed. The mixture is cast by melting and is subsequently cooled to form a billet which is worked utilizing one or both of equal channel angular extrusion and thermomechanical processing to form a target.

### TECHNICAL FIELD

The invention pertains to physical vapor deposition targets containing mixtures of copper and at least two additional elements. The invention additionally pertains to thin films and interconnects comprising mixtures of copper and two or more elements, and methods of forming copper-containing physical vapor deposition targets.

### BACKGROUND OF THE INVENTION

Physical vapor deposition (PVD) (e.g. sputtering) is frequently utilized for forming films of material across substrate surfaces. PVD can be utilized, for example, during semiconductor fabrication processes to form layers ultimately utilized in integrated circuitry structures and devices.

A typical PVD operation utilizes a target formed of a desired material to be deposited. The target is provided within a chamber of an appropriate apparatus. The substrate is provided in a location of the chamber spaced from the target and material of the target is sputtered or otherwise dislodged from the target and is deposited upon the substrate.

In particular applications, targets comprise copper materials which can be utilized to form conductive films across substrate surfaces. Exemplary applications for copper-containing conductive films are dual damascene processes in which copper-containing conductive films are utilized to form electrical interconnects. In dual damascene processes, a substrate is provided which has trenches, vias and/or other openings extending from an upper surface. In some applications copper-containing films are sputter-deposited within the openings and over regions of the substrate between the openings. The copper can then be removed from regions between the openings by, for example, chemical-mechanical polishing. The copper-containing film can be sputter-deposited to a sufficient thickness to completely fill the openings. However, sputter-deposition of the copper material is typically utilized to form a “seed layer” of copper-containing material where “seed layer” is used to refer to a thin film upon which a remaining thickness of copper can be grown utilizing methodology other than sputter-deposition. Exemplary methodology for providing an additional thickness of copper can be, for example, electrochemical deposition. Thus, a copper-containing interconnect will typically comprise two portions. A first portion will be a thin film corresponding to a sputter deposited seed layer, and a second portion (typically the majority or bulk of the interconnect) will be a layer formed over the seed layer by non-sputter depositing techniques.

Various difficulties can be encountered when PVD targets are utilized to sputter metal onto a substrate. In particular sputter applications the target can be subjected to intense power and heat. Such intense power and heat can cause targets to warp if the target does not have sufficient strength to contend with the high powers to which the target is subjected.

Films deposited through a physical vapor deposition process can also have various problems associated with them if the composition of the film is not appropriate. For instance, metal-containing films can exhibit reduced lifetimes due to stress-induced migration, electro-migration and/or corrosion. Additionally the films can have other undesirable properties such as poor adhesion to underlying materials of the substrate.

It would be desirable to develop target compositions which address one or more of the above-described problems and to develop methods for producing such target compositions.

### SUMMARY OF THE INVENTION

In one aspect the invention encompasses a physical vapor deposition target containing copper and at least two additional elements, a total amount of the at least two additional elements being from at least 100 ppm to less than about 10 atomic %. The invention additionally encompasses thin films and interconnects which contain the mixture of copper and at least two added elements where the total of the at least two added elements is from at least 100 ppm to less than about 10 atomic %.

In one aspect the invention encompasses forming a copper target. A mixture comprising copper and two or more elements selected from Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn and Zr is formed to have a total amount of the at least two elements from at least 100 ppm to less than about 10 atomic %. The mixture is cast by melting and is subsequently cooled to form a billet. The billet is worked to form a target where the working comprises one or both of equal channel angular extrusion and thermomechanical processing.

### BRIEF DESCRIPTION OF THE DRAWINGS

Preferred embodiments of the invention are described below with reference to the following accompanying drawings.

FIG. 1 is a diagrammatic cross-sectional view of an exemplary target/backing plate construction.

FIG. 2 is a top view of the FIG. 1 construction with the cross-section of FIG. 1 extending along line 1-1 of FIG. 2.

FIG. 3 is a diagrammatic cross-sectional view of a substrate at a particular processing step in accordance with the invention.

FIG. 4 shows the results of comparison studies of corrosion resistance of pure copper, binary alloys and exemplary materials in accordance with the invention.

FIG. 5 is a diagrammatic cross-sectional view of a substrate at a preliminary step of a processing method in accordance with the invention.

FIG. 6 is a view of the FIG. 5 wafer fragment at a processing step subsequent to that of FIG. 5.

FIG. 7 is a diagrammatic cross-sectional view of the FIG. 5 substrate at an alternative processing step subsequent to that of FIG. 5.

FIG. 8 shows a comparison of grain sizes of pure copper, binary copper alloys, and exemplary ternary copper materials formed in accordance with the invention.

FIG. 9 shows a comparison of the effects of heat treatment on ultimate tensile strength for pure copper, exemplary binary alloys, and an exemplary ternary copper material formed in accordance with the invention.

### DETAILED DESCRIPTION OF THE PREFERRED EMBODIMENTS

Interconnects based on copper technologies are replacing aluminum based technologies due to the lower electrical resistance of copper, improved electromigration resistance and lower costs of copper relative to aluminum. In a manner similar to aluminum, many properties of copper can be improved by additions of small amounts of other elements. Specifically, the use of alloys can reduce electromigration, stress-migration, corrosion and other undesirable effects relative to pure copper. It can be advantageous to use ternary and higher order copper-containing conductive materials to address various problems including, for example, problems associated with adhesion, stress-migration, electromigration, oxidation resistance, etc., while still maintaining a low overall electrical resistance in the conductive copper-containing material.

For purposes of interpreting this disclosure, a mixture of copper and two additional elements is referred to as a ternary copper-containing mixture. A mixture of copper and more than two additional elements is referred to as a copper-containing mixture having a higher order relative to ternary mixtures. The mixtures of the invention can be in any of numerous forms including compounds, alloys, complexes and interspersed materials. The mixtures utilized in the present invention are typically in the form of alloys and in the discussion below, the mixtures are referred to as alloys. It is to be understood however, that the mixtures can have forms other than true alloys and accordingly the exemplary materials referred to as alloys in the discussion that follows can in some aspects of the invention be in a form other than in true alloy form.

One benefit of utilizing ternary or higher order alloys of the invention relative to binary alloys is that the ternary and higher order alloys can provide additional freedom for addressing specific problems. For instance, particular elements when added to copper can primarily reduce electromigration while other elements can primarily reduce corrosion. Accordingly, when binary alloys are formed the alloys will typically be suitable for reducing electromigration or suitable for reducing corrosion but seldom are suitable for both. However, utilization of ternary or higher order alloys can allow both electromigration and corrosion to be addressed thereby allowing customization or tailoring of the alloy for a particular use or application. This combination of effects can also allow other undesirable aspects to be addressed.

It has been found that use of ternary or higher order mixtures of copper and additional elements can be utilized to simultaneously address multiple problems. In other words, it has been shown that for particular mixtures of alloying elements the benefits provided by independent elements can be combined to provide cumulative effects. In some instances, benefits or enhanced properties are observed for the ternary alloys where the total enhancement provided by the combination of alloying elements exceeds the independent enhancement of the property observed in the respective binary alloys. For example, addition of a total atomic amount “x” of a combination of a first and second element can provide an improvement in a property (such as corrosion resistance) relative to pure copper, which exceeds the observed improvement in that property for a binary alloy containing the same atomic amount “x” of the first element or second element independently. This enhanced improvement can also be accompanied by improvements in other properties as well. Similar effects can occur in higher order alloys.

An additional benefit of utilizing ternary or higher order alloys is that the enhanced properties of one or more alloy can be combined to allow a longer target life by the formation of a stronger target. It has been found that in some aspects a ternary or higher order alloy can advantageously increase target strength relative to binary alloys containing any of the elements present in the ternary or higher order alloy. Accordingly, the stronger targets are better able to withstand high power. Thus utilization of ternary and higher order alloys can allow problems to be addressed with sputtering targets and/or can allow problems to be addressed relative to films formed from the sputtering targets.

Utilization of ternary or higher order copper alloys can sometimes present difficulties in deposition since obtaining composition consistency in deposited films or materials can be increasingly difficult as mixtures become increasingly complex. Due to the unique properties of individual elements, elements in a mixture must be selected carefully to achieve desired chemical balance for consistent sputter deposition as well as production of a homogenous composition.

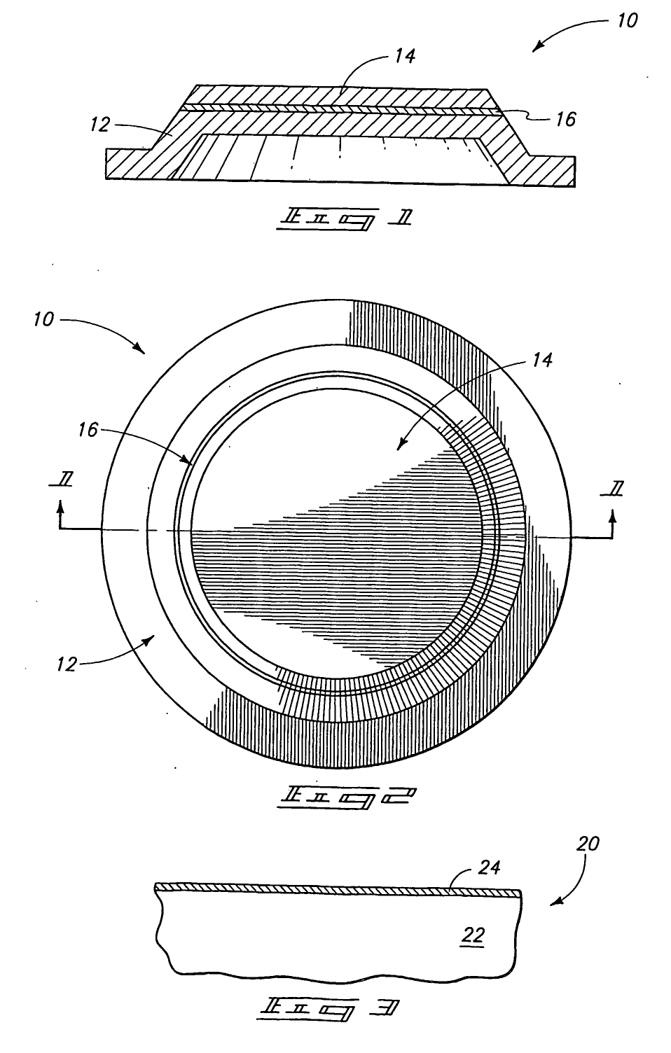

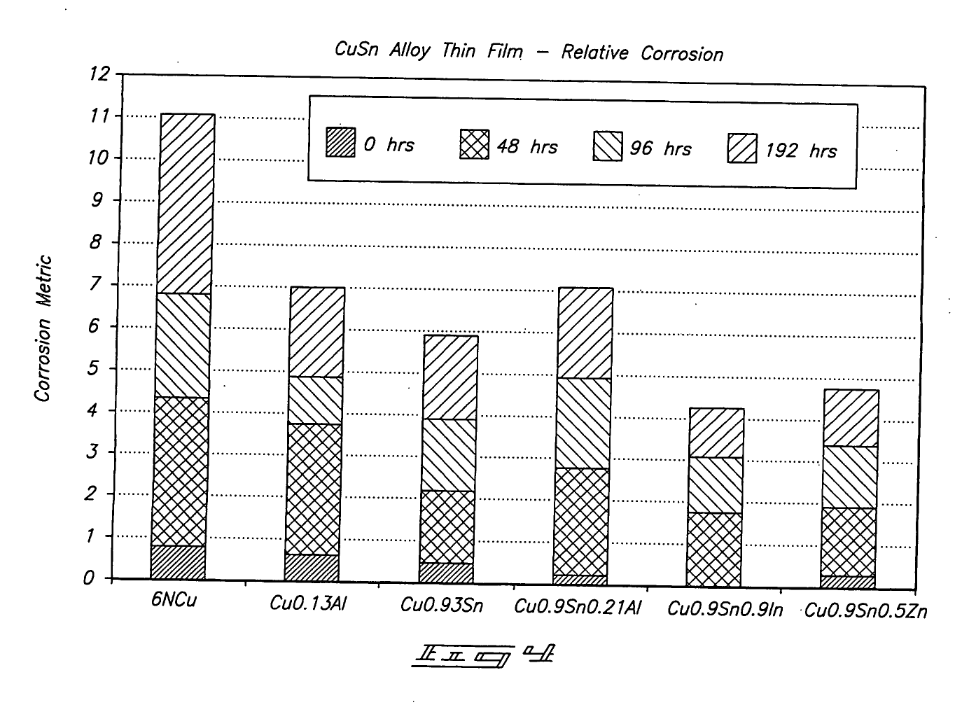

An exemplary target construction which can be formed in accordance with the methodology of the present invention (set forth below) is described generally with reference to FIGS. 1 and 2. A target construction 10 can include a target 14 bonded to a backing plate 12 through an interlayer 16. Target 14 can comprise ternary or higher order copper alloys, complexes or mixtures. Backing plate 12 can comprise any suitable material including but not limited to, for example, low purity copper. Interlayer 16 can constitute a diffusion bond formed directly between target 14 and backing plate 12, or can comprise one or more distinct materials provided to improve adhesion between target 14 and backing plate 12. Exemplary materials for interlayer 16 include, for example, one or more of silver, copper, nickel, tin and indium.

Target 14 can comprise ternary and higher order copper-containing mixtures having a variety of suitable compositions in accordance with the invention. In particular aspects, the copper-containing material will comprise copper together with two or more of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn and Zr. Typically, target 14 will consist essentially of the particular ternary or higher order copper-containing mixture and in particular applications will consist of copper together with the selected two or more elements. Target 14 contains from at least about 90 atomic % copper, to less than or equal to about 99.99 atomic % copper in addition to the two or more elements selected from the listed group. Preferably a total amount of the two or more elements present in the target will be from about 100 ppm, to less than about 10 atomic %. More preferably a combined total of the two or more elements present in total can be from at least at about 1000 ppm to less than about 2 atomic %.

Ternary copper materials in accordance with the invention can comprise, consist essentially of or consist of copper, a first element selected from the listed elements and a second element selected from the list of elements. The relative amounts of first and second elements is not limited to a particular value and can be, for example from about 100 ppm to about 10 atomic %. In particular instances, the amount of the first element and second element can be atomically equivalent relative to each other. For example, the invention encompasses targets containing copper and 0.5 atomic percent of a second element. Similarly, targets of the invention can comprise copper and 0.3 atomic percent of a first element and 0.3 atomic percent of a second element.

Exemplary ternary copper alloy materials which contain equivalent amounts of first and second added elements include Cu/0.5 at % Sn/0.5 at % Al; Cu/0.5 at % Sn/0.5 at % In; Cu/0.5 at % Sn/0.5 at % Zn; Cu/0.3 at % Ag/0.3 at/o Al; and Cu/0.3 at % Ag/0.3 at % Ti; where at % is atomic percent.

Where the copper material of the invention is a higher order copper alloy, the relative amounts of each non-copper element is not limited to any particular value. In particular instances, two or more of the non-copper elements can be present in equivalent amounts, atomically. Alternatively, the amount of each of the non-copper elements can differ relative to every other non-copper element.

Particular elements from the list of elements can be especially advantageous for ternary or higher order copper-containing alloys. For example, silver can be utilized to improve electromigration resistance due to its rapid diffusivity, low electrical resistivity and high atomic weight. Although titanium can increase electrical resistivity in materials, titanium can be utilized for improving corrosion resistance. Aluminum can also be utilized for improving corrosion resistance and may produce less degradation of electrical resistivity than titanium. It is to be noted that particular amounts of individual elements can be adjusted to provide or maximize a desired property in the target and/or resulting film or material.

Use of ternary or higher order copper alloys can permit customization or tailoring of thin films formed from exemplary copper alloy containing targets of the present invention. An exemplary thin film application in accordance with the invention is described with reference to FIG. 3.

A construction 20, which can be, for example, a semiconductor construction is shown to comprise a substrate 22. Substrate 22 can be for example, a monocrystalline silicon wafer. Although substrate 22 is shown as having a homogenous composition it is to be understood that the substrate can comprise numerous layers and integrated circuit devices (not shown). Substrate 22 independently or as combined with additional structures thereon can be referred to as a semiconductor substrate. To aid in interpretation of the claims that follow the terms “semiconductive substrate” and “semiconductor substrate” are defined to mean any construction comprising semiconductive material including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

A thin film 24 can be formed over substrate 22 by, for example, physical vapor depositing from a target comprising any of the above described ternary or higher order copper alloy materials. Physical vapor deposition utilizing a target encompassed by the invention can utilize conventional PVD methodology or methodology yet to be developed. Deposited film 24 can comprise any of the described ternary and higher order materials and can preferably be deposited to comprise ternary or higher order copper materials having a composition identical to that of the sputtering target. In particular instances, film 24 can consist essentially of the composition of the target and in particular instances can consist of the target composition.

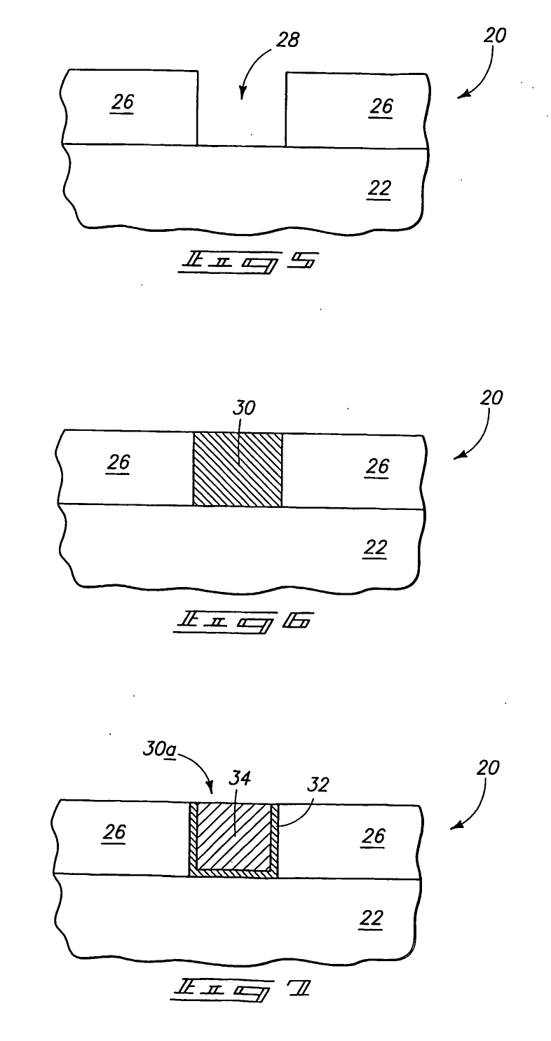

As discussed above, the ternary and higher order materials of the invention can confer desirable properties and in particular instances can confer a combination of desirable properties to thin film 24 which are improved relative to a binary alloy comprising copper and one of the added elements present in the material of film 24. For example, film 24 can have improved electromigration resistance, decreased electrical resistivity and/or improved corrosion resistance relative to binary alloys. FIG. 4 shows results of studies of corrosion resistance for exemplary ternary materials of the invention. The results show that ternary copper mixtures of the invention having particular combinations of elements can increase corrosion resistance beyond the level or resistance achieved in binary copper alloys having either element alone.

Use of ternary or higher order copper alloys can permit customization of thin film 24 to impart desired properties for a particular application. Additionally, particular combinations of elements can provide enhanced consistency of composition throughout thin film 24. Further, alloying elements can be chosen to enhance adhesion of layer 24 to an underlying material. The ratio of the added elements can be adjusted to maximize enhancement of a particular property or to achieve a desired balance of combined property improvements in thin film 24.

Layer 24 is not limited to a particular thickness and can have a thickness of, for example, from about 0.1 microns to about 2.0 microns. Sputter deposition from a target of the invention can be utilized to form layer 24 across a smooth and substantially planar substrate surface as shown in FIG. 3. Alternatively, layer 24 can be formed across a surface having various topological features.

An exemplary application where targets and compositions of the invention can be particularly useful is formation of interconnects. Various interconnects formed in accordance with the invention are described with reference to FIGS. 5-7. Referring initially to FIG. 5, a construction 20 is shown as having a material 26 deposited over an upper surface of substrate 22. Material layer 26 is not limited to a particular type of material and can be, for example, an insulative material. An opening 28 is provided which extends from an upper surface through material 26 and can in particular instances be provided such that a surface of substrate 22 is exposed at the base of the opening. Such exposed surface can be, for example, a node location in substrate 22.

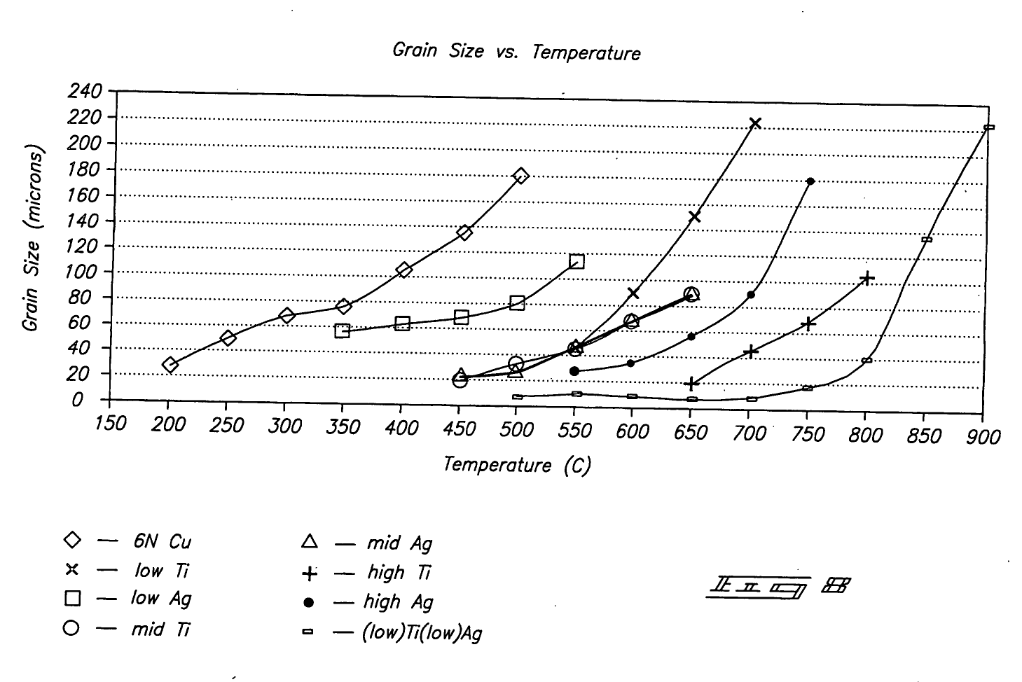

Referring to FIG. 6, an interconnect material 30 can be provided within the opening. Formation of interconnect 30 can comprise, for example, sputtering from a target of the invention sufficient to fill opening 28. In particular instances, formation of interconnect 30 can comprise depositing material from a target of the invention to cover some or all of insulative material 26. The portions of the deposited material overlying layer 26 can be subsequently removed, by for example, chemical-mechanical polishing or other conventional or yet to be developed removal technique. Interconnect 30 can comprise any of the ternary materials or higher order materials described above, and in particular instances can consist essentially of or consist of a composition identical to that provided in the sputtering target.

Referring to FIG. 7, such shows an alternative processing relative to that shown in FIG. 6. As shown in FIG. 7, via or opening 28 (FIG. 5) can be filled by providing an initial thin film or “seed layer” 32 within the opening and subsequently filling an interior portion of the opening with an additional material 34 to form interconnect 30a. In such embodiment, seed layer 32 can line the via or opening and can substantially separate material 34 from insulative layer 26. Seed layer 32 can preferably comprise any of the ternary or higher order materials described above and can be deposited preferably utilizing physical vapor deposition. Interconnect fill material 34 can comprise pure copper, any of the ternary or higher order copper alloys described above or alternative conductive materials including non-copper materials. In particular instances, materials 32 and 34 can be identical. Material 34 can be deposited to fill the via either partially (not shown) or completely as shown in FIG. 7. Interconnect material 34 can be deposited by physical vapor deposition or can be provided by alternative means such as, for example, electrochemical deposition.

Methodology utilized for forming the construction 20 as shown in FIG. 7 can in particular instances comprise providing one or both of materials 32 and 34 to overly some or all of an upper surface of insulative layer 26. The overlying material can be planarized and/or removed from over material 26 by, for example, chemical mechanical polishing or other conventional techniques.

In addition to utilization for PVD processes for forming the described layers, it is to be understood that the ternary and higher order materials of the invention can be deposited using alternative techniques including but not limited to atomic layer deposition, chemical vapor deposition and electrochemical deposition.

The use of ternary or higher order copper alloys for interconnect applications can impact interconnect properties by, for example, simultaneously reducing stress induced migration, electromigration and corrosion in the interconnect. These alloys can additionally improve adhesion to other underlying materials relative to the adhesion provided by pure copper or binary alloys. Where the ternary or higher order copper alloy materials of the invention are utilized as a seed layer such as layer 32 shown in FIG. 7, such can provide enhanced adhesion to alternative underlying materials (not shown) such as barrier materials, and can additionally advantageously impact properties such as agglomeration, stress migration, bulk copper diffusion, grain size, oxidation resistance and electromigration resistance. Appropriate combinations of alloying elements such as those described above can be chosen to impact interconnect properties through diffusion into a bulk copper material which is subsequently formed over the sputter deposited layer (such as material 34).

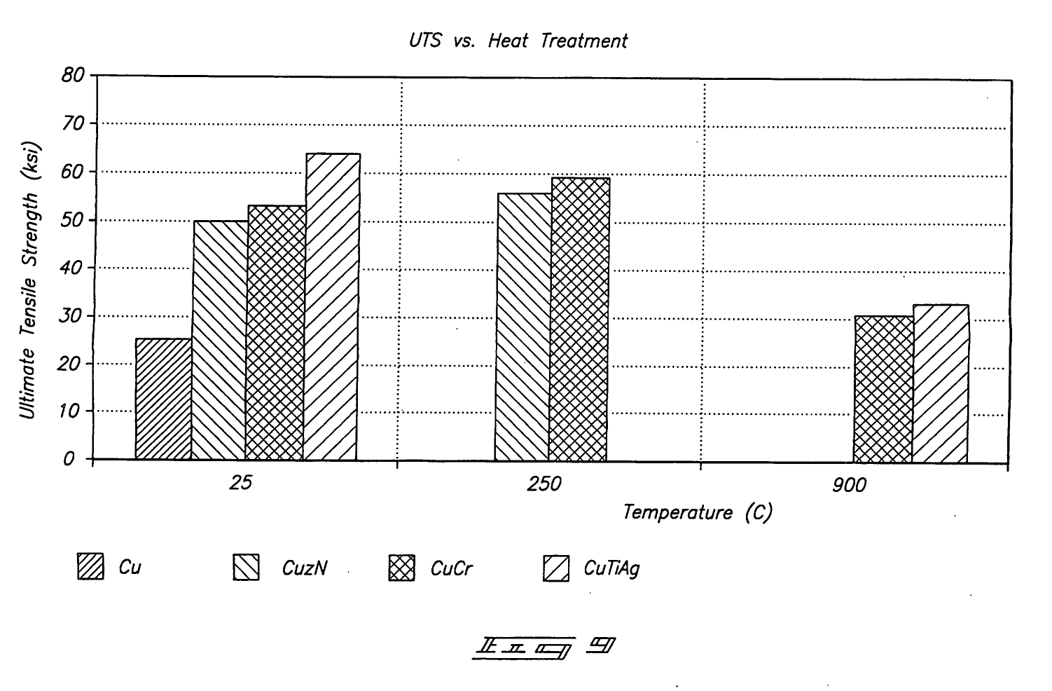

In addition to the improved properties of layers and interconnects comprising materials sputter deposited from targets of the inventions, the ternary or higher order alloys described can improve properties of the targets themselves relative to targets of binary alloys or pure copper. The improved properties can include, for example, retardation of grain growth within the target material which can in turn lead to better uniformity of thin films or other layers deposited from the target. A comparison of grain sizes as a function of temperature for pure copper, binary copper alloys containing various amounts of either Ti or Ag, and a ternary copper alloy of the invention containing both Ti and Ag is shown in FIG. 8.

The ternary and higher order alloys can additionally provide increased target strength due to material composition and the resulting small grain sizes which can be achieved in the targets of the invention. A comparison of the ultimate tensile strength of pure copper, binary copper alloys containing Zn or Cr, and a ternary copper alloy of the invention containing Ti and Ag is shown in FIG. 9. The increased target strength can enable the ternary or higher order alloy targets to withstand higher sputtering powers and can provide longer target life.

Targets in accordance with the invention can be formed to comprise ternary or higher order mixtures of copper-containing materials, with methodology involving the following. Initially, the copper and other desired elements are cast by melting. Such melting can be achieved utilizing, for example, melting of components in a crucible. The components can be provided in elemental form, from one or more master alloy(s) or combination thereof to obtain the desired content of individual elements. The molten material is subsequently cooled to form a hardened uniform (i.e. homogenous) mixture of the copper and additional elements. The casting can typically be conducted under a vacuum or other inert environment.

Billets formed by the casting can then undergo appropriate working to induce desired properties and can be formed into desired target shapes. The working can include, for example, thermo-mechanical processing with appropriate subsequent heat treatments tailored to the specific alloy composition. Additionally or alternatively, the working can involve equal channel angular extrusion (ECAE) to reduce grain size and/or influence a desired crystallographic orientation. The ultimate shape of the targets can be such that the targets are configured to be bonded to a backing plate to form a target assembly such as shown in FIGS. 1 and 2. Alternatively, the targets can be configured to be utilized as a monolithic target where the term “monolithic” refers to a target utilized with bonding to a backing plate.

The invention claimed is:

1. A physical vapor deposition target comprising:
greater than or equal to 90 atomic percent copper;
a first added element; and
a second added element, the first and second added elements each being selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr.

2. The physical vapor deposition target of claim 1 wherein a total combined amount of the first and second added elements present in the target is from at least 100 ppm to less than about 10 atomic %.

3. The physical vapor deposition target of claim 1 wherein the target consists essentially of copper and the first and second added elements.

4. The physical vapor deposition target of claim 1 wherein the first and second added elements are each present in the target at 0.5 atomic percent.

5. The physical vapor deposition target of claim 1 wherein the first and second added elements are each present in the target at 0.3 atomic percent.

6. The physical vapor deposition target of claim 1 wherein the first and second added elements are present in the target in equivalent atomic percent relative to each other.

7. The physical vapor deposition target of claim 6 wherein the first added element is Sn, or Ag.

8. The physical vapor deposition target of claim 7 wherein the second added element is Al, Zn, In, or Ti.

9. The physical vapor deposition target of claim 1 further comprising a third added element selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr.

10. The physical vapor deposition target of claim 9 wherein the target consists essentially of copper and the first, second and third added elements.

11. A physical vapor deposition target comprising:
copper; and
at least two elements selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr, a total amount of the at least two elements present in the target being from at least 100 ppm to less than about 1 atomic %.

12. The physical vapor deposition target of claim 11 wherein the total amount of the at least two elements is from about 1000 ppm to less than about 2 atomic percent.

13. The physical vapor deposition target of claim 11 wherein the at least two elements include one or more of Sn, Al, In, Ti, Ag and Zn.

14. The physical vapor deposition target of claim 11 wherein the target comprises a ternary mixture of copper and two additional elements.

15. The physical vapor deposition target of claim 14 wherein the target consists essentially of the ternary mixture.

16. The physical vapor deposition target of claim 14 wherein the ternary mixture is a ternary alloy.

17. An interconnect comprising a mixture of copper and two or more elements selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr, a total amount of the at least two elements present in the interconnect being from at least 100 ppm to less than about 10 atomic %.

18. The interconnect of claim 17 wherein the two or more elements includes a first element and a second element, the first and second elements being present in atomic equivalent amounts within the mixture relative to each other.

19. The interconnect of claim 18 wherein the first and second elements are each present in the mixture at 0.5 atomic percent.

20. The interconnect of claim 18 wherein the first and second elements are each present in the mixture at 0.3 atomic percent.

21. A thin film comprising a mixture of copper and two or more elements selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr, a total amount of the at least two elements present in the thin film being from at least 100 ppm to less than about 10 atomic %.

22. The thin film of claim 21 wherein the mixture is a ternary mixture.

23. The thin film of claim 21 wherein the mixture comprises a first element selected from Sn and Ag, and a second element selected from In, Zn, Ti and Al.

24. The thin film of claim 23 wherein the first and second elements are present in the mixture at an equivalent atomic percent relative to each other.

25. A method of forming a copper target, comprising:
forming a mixture comprising copper and two or more elements selected from the group consisting of Ag, Al, As, Au, B, Be, Ca, Cd, Co, Cr, Fe, Ga, Ge, Hf, Hg, In, Ir, Li, Mg, Mn, Nb, Ni, Pb, Pd, Pt, Sb, Sc, Si, Sn, Ta, Te, Ti, V, W, Zn, and Zr, a total amount of the at least two elements present in the mixture being from at least 100 ppm to less than about 10 atomic %;
casting the mixture by melting and subsequent cooling to form a billet; and
working the billet to form a target, the working comprising one or more of equal channel angular extrusion, and thermomechanical processing.

26. The method of claim 25 wherein the mixture is a ternary mixture.

27. The method of claim 25 wherein the mixture consists essentially of copper and the at least two elements.

28. The method of claim 25 wherein the two or more elements includes a first element and a second element, the first and second elements being present in atomic equivalent amounts within the mixture relative to each other.

29. The method of claim 25 wherein the mixture is present in the target in an alloy form.

30. The method of claim 25 wherein the target is monolithic.

31. The method of claim 25 wherein the forming the target comprises bonding the target to a backing plate.
